(19) United States
(12) Patent Application Publication
(10) Pub. No.: US 2016/0138157 A1
(43) Pub. Date: May 19, 2016

(54) THIN FILM DEPOSITION APPARATUS

(71) Applicant: SAMSUNG DISPLAY CO., LTD., Yongin-City (KR)

(72) Inventors: Choel Min JANG, Seoul (KR); Myung Soo HUH, Suwon-si (KR); Nam HA, Hwaseong-si (KR); Dong Kyun KO, Hwaseong-si (KR); In Kyo KIM, Seongnam-si (KR)

(21) Appl. No.: 14/702,985

(22) Filed: May 4, 2015

(30) Foreign Application Priority Data
Nov. 14, 2014 (KR) 10-2014-0158978

(51) Int. Cl. C23C 16/455; C23C 16/50; C23C 16/44

(52) U.S. Cl. CPC C23C 16/45563; C23C 16/4412; C23C 16/45544; C23C 16/50

(57) ABSTRACT

A thin film deposition apparatus, including a plurality of linear nozzle parts separated from each other; and an exhaust plate to which is attached the plurality of linear nozzle parts, each linear nozzle part including a linear body member; a pair of first reaction gas pipes in the linear body member and inflowing a first reaction gas; a second reaction gas pipe between the pair of first reaction gas pipes and inflowing a second reaction gas; and a pair of control gas pipes between each of the first reaction gas pipes and the second reaction gas pipe and inflowing a control gas controlling a flow of the second reaction gas.

### CROSS-REFERENCE TO RELATED APPLICATION

Korean Patent Application No. 10-2014-0158978, filed on Nov. 14, 2014, in the Korean Intellectual Property Office, and entitled: “Thin Film Deposition Apparatus,” is incorporated by reference herein in its entirety.

### BACKGROUND

1. Field

The present disclosure relates to a thin film deposition apparatus.

2. Description of the Related Art

Methods for depositing a thin film of a predetermined thickness on a substrate include physical vapor deposition (PVD) using a physical collision such as sputtering and chemical vapor deposition (CVD) using a chemical reaction. In CVD, a reaction product generated by simultaneously injecting a plurality of reaction gases inside a chamber may be deposited on the substrate. When simultaneously injecting the reaction gases into the chamber by the CVD method, particles may be generated by the reaction on the substrate as well as the reaction in the substrate surface, film formation speed may be high, for example, more than 100 nm/min, and it may be difficult to form a dense thin film.

### SUMMARY

Embodiments may be realized by providing a thin film deposition apparatus, comprising a plurality of linear nozzle parts separated from each other; and an exhaust plate to which is attached the plurality of linear nozzle parts, each linear nozzle part including a linear body member; a pair of first reaction gas pipes in the linear body member and inflowing a first reaction gas; a second reaction gas pipe between the pair of first reaction gas pipes and inflowing a second reaction gas; and a pair of control gas pipes between each of the first reaction gas pipes and the second reaction gas pipe and inflowing a control gas controlling a flow of the second reaction gas.

The linear nozzle part may further include a pair of first reaction gas nozzle parts in the linear body member and connected to the pair of first reaction gas pipes; a second reaction gas nozzle part in the linear body member and connected to the second reaction gas pipe; and a pair of control nozzle parts in the linear body member and connected to the pair of control gas pipes.

The control gas may enclose the second reaction gas to control a degree of mixing of the second reaction gas and the first reaction gas.

The control gas may be an inert gas.

Each first reaction gas nozzle part may include a first reaction gas diffusion part including concave groove at a bottom surface of the linear body member, and a first reaction gas connection part connecting the first reaction gas pipe and the first reaction gas diffusion part.

The second reaction gas nozzle part may include a plurality of second reaction gas nozzles separated from each other, and a second reaction gas diffusion part connected to the second reaction gas nozzle and including a concave groove at a bottom surface of the linear body member.

The second reaction gas may mix with the first reaction gas after leaving the second reaction gas nozzle part and the pair of first reaction gas nozzle parts, respectively.

The thin film deposition apparatus may further include nozzle exhaust parts between the plurality of linear nozzle parts. The exhaust plate may include a plurality of exhaust ports, and the nozzle exhaust parts may correspond to the plurality of exhaust ports.

The plurality of linear nozzle parts may be separated from a substrate deposited with a thin film and positioned upwardly with respect to the substrate.

The thin film deposition apparatus may further include a transferring device supporting the substrate and transferring the substrate.

The thin film deposition apparatus may further include a plasma generation electrode installed inside the first reaction gas pipe.

### BRIEF DESCRIPTION OF THE DRAWINGS

Features will become apparent to those of skill in the art by describing in detail exemplary embodiments with reference to the attached drawings in which:

FIG. 1 illustrates a perspective view of a thin film deposition apparatus according to an exemplary embodiment;

FIG. 2 illustrates a front view of a thin film deposition apparatus according to an exemplary embodiment;

FIG. 3 illustrates an enlarged perspective view of a part of a front surface of a thin film deposition apparatus according to an exemplary embodiment;

FIG. 4 illustrates an enlarged perspective view of a part of a lower surface of a thin film deposition apparatus according to an exemplary embodiment;

FIG. 5 illustrates an enlarged front view of a part for explaining an operation state of a thin film deposition apparatus according to an exemplary embodiment;

FIG. 6 illustrates a graph comparing a film formation speed of a thin film deposition apparatus according to an exemplary embodiment and a comparative atomic layer deposition apparatus; and

FIG. 7 illustrates a graph comparing thin film uniformity of a thin film deposition apparatus according to an exemplary embodiment and a comparative atomic layer deposition apparatus.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

Throughout the specification, unless explicitly described to the contrary, the word “comprise” and variations such as “comprises” or “comprising” will be understood to imply the inclusion of stated elements but not the exclusion of any other elements. In addition, it will be understood that when an element such as a layer, film, region, or substrate is referred to as being “on” another element, it can be “directly on” the other element or intervening elements may also be present throughout the specification. In addition, the word “on” means positioning on or below an object portion, but does not essentially mean positioning on the upper side of the object portion based on a gravity direction. In addition, it will also be understood that when an element is referred to as being “between” two elements, it can be the only element between the two elements, or one or more intervening elements may also be present.

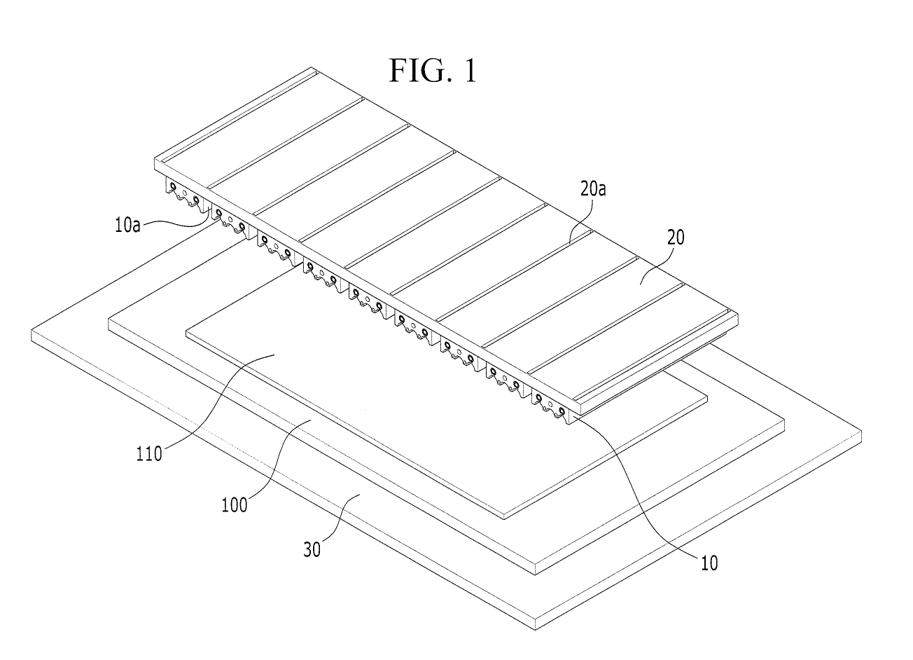

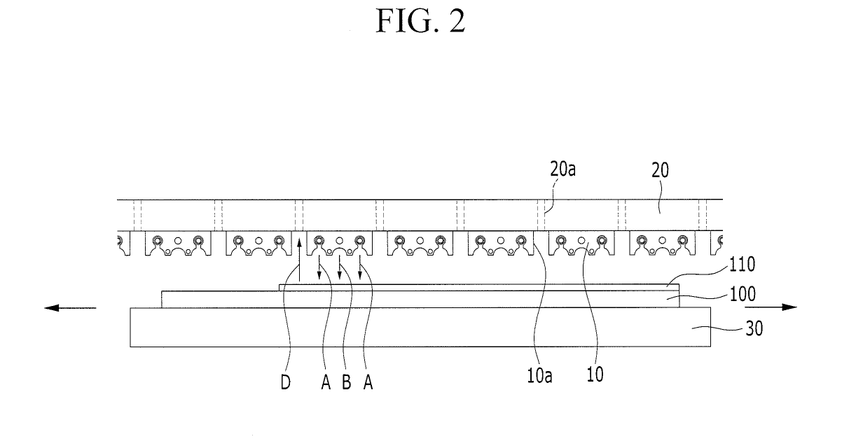

FIG. 1 illustrates a perspective view of a thin film deposition apparatus according to an exemplary embodiment, and FIG. 2 illustrates a front view of a thin film deposition apparatus according to an exemplary embodiment.

As shown in FIG. 1 and FIG. 2, a thin film deposition apparatus according to an exemplary embodiment may include a plurality of linear nozzle parts 10 positioned upwardly to be separated from a substrate 100 deposited with a thin film 110, an exhaust plate 20 to which a plurality of linear nozzle parts 10 are attached, and a transferring device 30 supporting the substrate 100 and transferring the substrate 100.

An interval between the adjacent linear nozzle parts 10 may form a nozzle exhaust part 10a, and the exhaust plate 20 may have, e.g., include, a plurality of exhaust ports 20a formed to be separated by a predetermined interval. The exhaust port 20a may be installed at a position corresponding to the nozzle exhaust part 10a.

The thin film 110 may be deposited on the substrate 100 by a mixture reaction of a first reaction gas A and a second reaction gas B sprayed from the linear nozzle part 10. A product D generated after the mixture reaction of the first reaction gas A and the second reaction gas B may be transmitted to the exhaust port 20a through the nozzle exhaust part 10a and may be discharged outside through the exhaust port 20a, and a pure thin film 110 having a low impurity content may be deposited.

The thin film 110 may be deposited on the substrate 100 while transferring the substrate 100 by using the transferring device 30. The linear thin film may be deposited by a number of a plurality of linear nozzle parts 10 on the substrate 100, linear thin films may be continuously formed, and the thin film 110 may be formed on the entire region on the substrate 100. The substrate 100 may be transferred in one direction or both directions by using the transferring device 30, and when reciprocally moving the substrate 100 by using the transferring device 30, the thin film 110, e.g, of a preferable thickness, may be formed according to a reciprocation time. The thin film may be deposited on the entire region of the substrate while transferring the substrate by using the transferring device. In an embodiment, the thin film may be deposited on the entire region of the substrate while transferring the linear nozzle part and the exhaust plate.

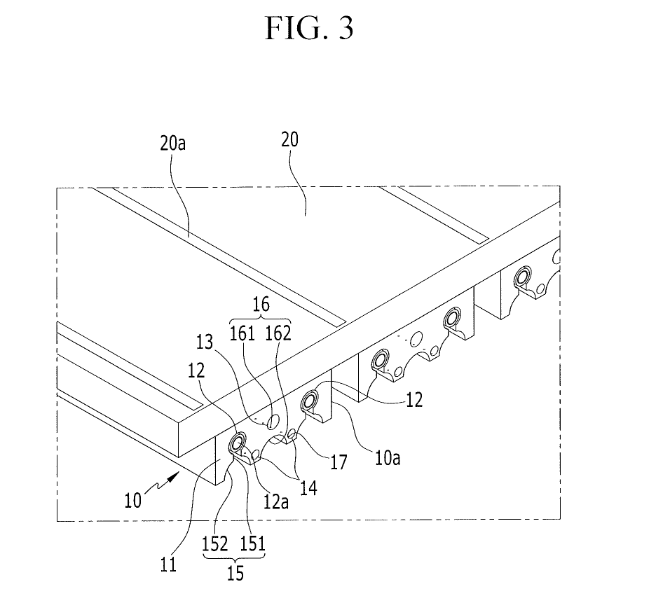

Next, a structure and an operation of the linear nozzle part of the thin film deposition apparatus according to an exemplary embodiment will be described with reference to FIG. 3 to FIG. 5.

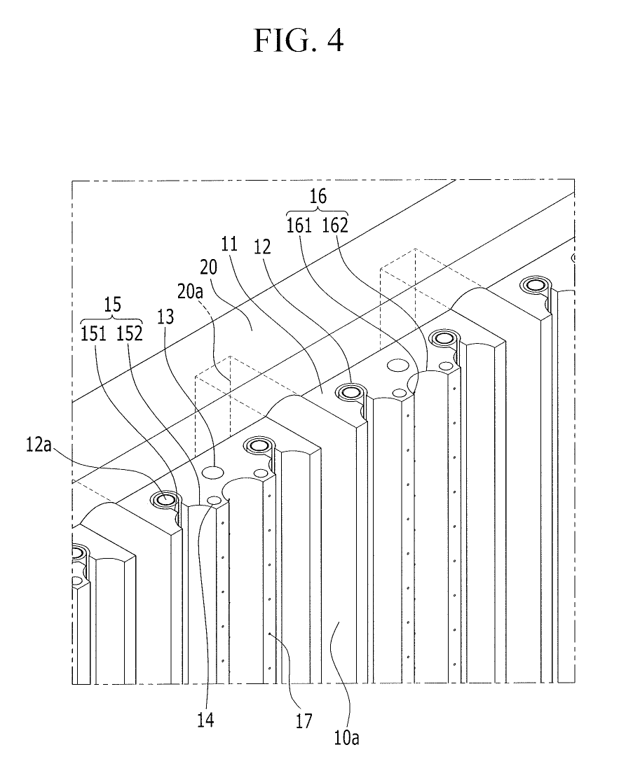

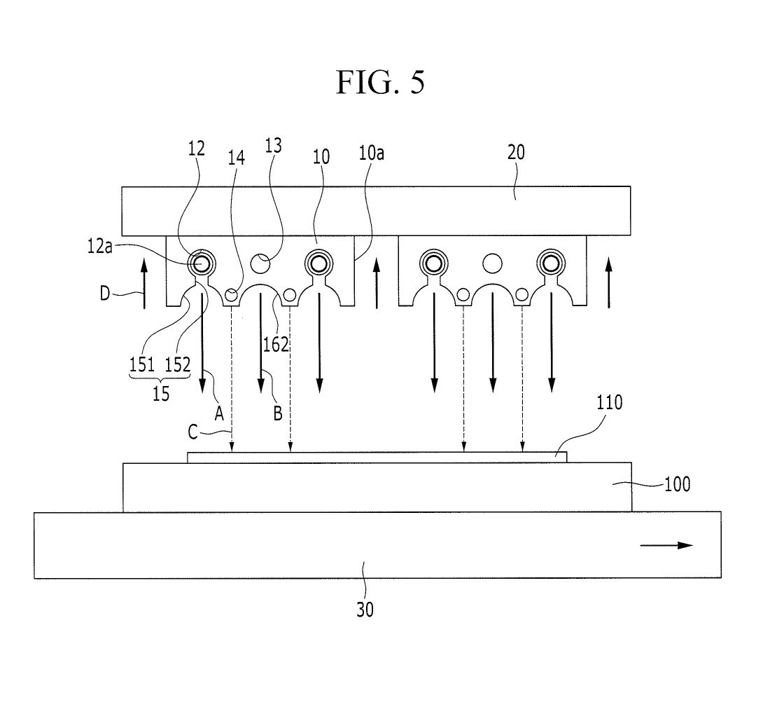

FIG. 3 illustrates an enlarged perspective view of a part of a front surface of a thin film deposition apparatus according to an exemplary embodiment, FIG. 4 illustrates an enlarged perspective view of a part of a lower surface of a thin film deposition apparatus according to an exemplary embodiment, and FIG. 5 illustrates an enlarged front view of a part for explaining an operation state of a thin film deposition apparatus according to an exemplary embodiment.

As shown in FIG. 3 to FIG. 5, one linear nozzle part 10 of the thin film deposition apparatus according to an exemplary embodiment may include a linear body member 11 formed with a long bar shape, a pair of first reaction gas pipes 12 formed at, e.g., in, the linear body member 11, a second reaction gas pipe 13 formed between a pair of first reaction gas pipes 12, and a pair of control gas pipes 14 formed between the first reaction gas pipe 12 and the second reaction gas pipe 13.

A pair of first reaction gas pipes 12 may be formed to be separated from each other, and the first reaction gas A may flow in from the outside and may flow along the first reaction gas pipes 12. A plasma generation electrode 12a may be installed inside the first reaction gas pipe 12, and the first reaction gas A may be in a plasma state. The second reaction gas pipe 13 may transfer the second reaction gas B from the outside that is mixed with the first reaction gas A to form the thin film 110. The second reaction gas B may be a material that becomes a main source, e.g., a source of material for the thin film 110. For a pair of control gas pipes 14, the control gas C that may control the flow of the second reaction gas B may flow in from the outside along the control gas pipe 14. A pair of first reaction gas pipes 12 and a second reaction gas pipe 13 may be formed with the same height, e.g., at a same position in a direction in which gas is discharged from the first reaction gas pipes 12 and second reaction gas pipe 13, and a pair of control gas pipes 14 may be formed at a lower position than the first reaction gas pipe 12 and the second reaction gas pipe 13.

The linear nozzle part 10 may further include a pair of first reaction gas nozzle parts 15 formed at e.g., in, the linear body member 11, a second reaction gas nozzle part 16, and a control nozzle part 17.

The first reaction gas nozzle parts 15 may respectively be connected to a pair of first reaction gas pipes 12. The first reaction gas nozzle part 15 may further include a first reaction gas diffusion part 151 formed of, e.g., including, a concave groove at a bottom surface of the linear body member 11, and a first reaction gas connection part 152 connecting the first reaction gas pipe 12 and the first reaction gas diffusion part 151. The first reaction gas A flowing in through the first reaction gas pipe 12 may be linearly discharged downwardly through the first reaction gas connection part 152 and may be sprayed downwardly to a wider area through the first reaction gas diffusion part 151 to be deposited on the substrate 100.

The second reaction gas nozzle part 16 may be connected to the second reaction gas pipe 13. The second reaction gas nozzle part 16 may include a plurality of second reaction gas nozzles 161 formed in a line to be separated from each other at the lower surface of the second reaction gas pipe 13, and a second reaction gas diffusion part 162 connected to the second reaction gas nozzle 161 and formed of, e.g., including, the concave groove at the bottom surface of the linear body member 11. The second reaction gas B flowing in through the second reaction gas pipe 13 may be discharged with a point shape through a plurality of second reaction gas nozzles 161, e.g., a shape corresponding to that of second reaction gas nozzles 161, and may be sprayed downwardly in a wider area through the second reaction gas diffusion part 161 to be disposed on the substrate 100.

A pair of control nozzle parts 17 may be connected to a pair of control gas pipes 14. The control nozzle part 17 may corresponds to a plurality of control nozzles formed at the lower surface of the control gas pipe 14 to be separated from each other.

As shown in FIG. 5, the first reaction gas A and the second reaction gas B may simultaneously be sprayed to the substrate 100 through the first reaction gas nozzle part 15 and the second reaction gas nozzle part 16, and the first reaction gas A and the second reaction gas B may be mixed at the surface of the substrate 100 to form the thin film 110. The nozzle exhaust part 10a and the exhaust port 20a may be installed outside the first reaction gas nozzle part 15, and the product D generated in the mixture process may be discharged through the nozzle exhaust part 10a and the exhaust port 20a.

The control gas C sprayed to the substrate 100 through the control nozzle part 17 may control the flow of the second reaction gas B, and a mixture degree, e.g., a degree of mixing, of the first reaction gas A and the second reaction gas B may be controlled. The control gas (C) may be an inert gas, for example, argon (Ar).

For example, the control gas C may be sprayed from the control nozzle part 17 onto the surface of the substrate 100, the second reaction gas B may not be mixed with the first reaction gas A on the substrate 100 by the control gas C enclosing the second reaction gas B, e.g., the control gas C separating the second reaction gas B from the first reaction gas A by being between the second reaction gas B and the first reaction gas A, and second reaction gas B may reach the surfaces of the substrate 100. After the first reaction gas A and the second reaction gas B are maximally absorbed to, e.g., by, the surface of the substrate 100, the first reaction gas A and the second reaction gas B may be mixed at the surface of the substrate 100 to form the thin film 110.

As described above, the first reaction gas A and the second reaction gas B may be mixed at the surface of the substrate 100 by the control nozzle part 17 enclosing the second reaction gas nozzle part 16, e.g., the control nozzle part 17 separating the second reaction gas nozzle part 16 from the first reaction gas nozzle part 15 by being between the second reaction gas nozzle part 16 and the first reaction gas nozzle part 15, to form the thin film 110 and the product D may be discharged through the exhaust port 20a without generation of particles, and the pure thin film 110 having a lower impurity content may be deposited, and the first reaction gas A and the second reaction gas B may simultaneously be sprayed and the timing of the mixture of the first reaction gas A and the second reaction gas B may be controlled through the control gas C, and the film formation speed may be improved.

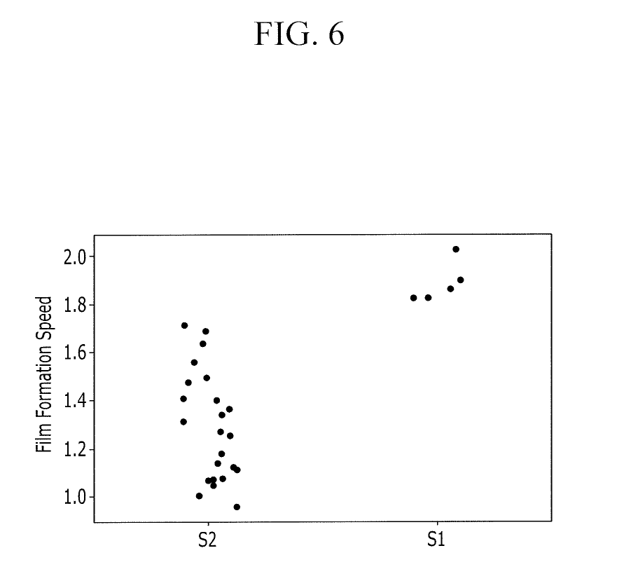

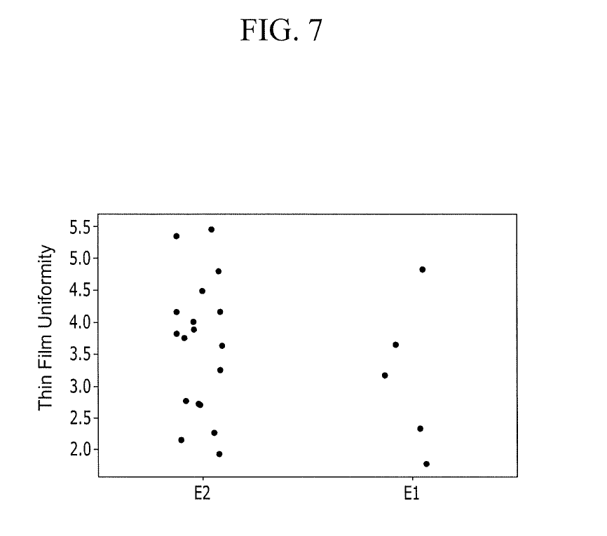

FIG. 6 illustrates a graph comparing a film formation speed of a thin film deposition apparatus according to an exemplary embodiment and a comparative atomic layer deposition apparatus, and FIG. 7 illustrates a graph comparing thin film uniformity of a thin film deposition apparatus according to an exemplary embodiment and a comparative atomic layer deposition apparatus.

As shown in FIG. 6, the film formation speed S1 of the thin film deposition apparatus according to an exemplary embodiment is higher than the film formation speed S2 of a comparative atomic layer deposition apparatus by about 30%, and as shown in FIG. 7, the thin film uniformity E1 of the thin film deposition apparatus according to an exemplary embodiment and the thin film uniformity E2 according to a comparative atomic layer deposition apparatus are similar.

In an embodiment, the same second reaction gas B may be supplied to all linear nozzle parts 10, the second reaction gas may be supplied to some linear nozzle parts, and the third reaction gas different from the second reaction gas may be supplied to the other linear nozzle parts to form the complex thin film. For example, TMA (trimethylaluminum) may be supplied to the second reaction gas pipe formed at some linear nozzle parts and TEMAZ (tetrakis-ethylmethylamino zirconium) may be supplied to the second reaction gas pipe formed at the other linear nozzle parts to form the complex thin film.

The plurality of linear nozzle parts may be attached to the exhaust plate to be connected to each other, the size of the thin film deposition apparatus may be extended according to the size of the substrate, and cleaning and replacement of the linear nozzle parts may be simplified.

A heater (not shown) may be installed between the exhaust plate and the linear nozzle part, and liquefaction of the first reaction gas and the second reaction gas may be prevented.

By forming the thin film by exposing the second reaction gas to the first reaction gas after previously oversaturating the second reaction gas to the surface of the substrate, the film formation speed may be further improved.

By way of summation and review, an atomic layer deposition (ALD) method may include low particle generation and formation of a dense thin film. In the ALD method, the reaction gas including one source material may be injected inside a chamber to be absorbed to, e.g., by, a heated substrate, and then the reaction gas including another source material may be injected inside the chamber to deposit the product by a chemical reaction between the source materials in the substrate surface. The ALD may have excellent step coverage and may allow deposition of a pure thin film having a low impurity content. The ALD method may have low film formation speed, and manufacturing time and manufacturing cost using the ALD method may be high.

The present disclosure provides a thin film deposition apparatus that may increase a film formation speed and simultaneously may form a dense thin film.

According to an exemplary embodiment of the present disclosure, by installing the control nozzle part enclosing the second reaction gas nozzle part, e.g., the control nozzle part separating the second reaction gas nozzle part from the first reaction gas nozzle part by being between the second reaction gas nozzle part and the first reaction gas nozzle part, the first reaction gas and the second reaction gas may be mixed to form the thin film at the surface of the substrate without generation of particles. The thin film having a low impurity content may be deposited and the timing of the mixture of the first reaction gas and the second reaction gas may be controlled, and the film formation speed may be improved.

By installing the nozzle exhaust part and the exhaust port, the product may be discharged through the nozzle exhaust part and the exhaust port, and a pure thin film having a low impurity content may be deposited.

Example embodiments have been disclosed herein, and although specific teems are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A thin film deposition apparatus, comprising:
a plurality of linear nozzle parts separated from each other; and
an exhaust plate to which is attached the plurality of linear nozzle parts,
each linear nozzle part including:
a linear body member;
a pair of first reaction gas pipes in the linear body member and inflowing a first reaction gas;
a second reaction gas pipe between the pair of first reaction gas pipes and inflowing a second reaction gas; and
a pair of control gas pipes between each of the first reaction gas pipes and the second reaction gas pipe and inflowing a control gas controlling a flow of the second reaction gas.

2. The thin film deposition apparatus as claimed in claim 1, wherein the linear nozzle part further includes:
a pair of first reaction gas nozzle parts in the linear body member and connected to the pair of first reaction gas pipes;
a second reaction gas nozzle part in the linear body member and connected to the second reaction gas pipe; and
a pair of control nozzle parts in the linear body member and connected to the pair of control gas pipes.

3. The thin film deposition apparatus as claimed in claim 2, wherein the control gas encloses the second reaction gas to control a degree of mixing of the second reaction gas and the first reaction gas.

4. The thin film deposition apparatus as claimed in claim 3, wherein the control gas is an inert gas.

5. The thin film deposition apparatus as claimed in claim 2, wherein each first reaction gas nozzle part includes a first reaction gas diffusion part including concave groove at a bottom surface of the linear body member, and a first reaction gas connection part connecting the first reaction gas pipe and the first reaction gas diffusion part.

6. The thin film deposition apparatus as claimed in claim 5, wherein the second reaction gas nozzle part includes a plurality of second reaction gas nozzles separated from each other, and a second reaction gas diffusion part connected to the second reaction gas nozzle and including a concave groove at a bottom surface of the linear body member.

7. The thin film deposition apparatus as claimed in claim 2, wherein the second reaction gas mixes with the first reaction gas after leaving the second reaction gas nozzle part and the pair of first reaction gas nozzle parts, respectively.

8. The thin film deposition apparatus as claimed in claim 1, further comprising nozzle exhaust parts between the plurality of linear nozzle parts,
wherein:
the exhaust plate includes a plurality of exhaust ports, and
the nozzle exhaust parts corresponds to the plurality of exhaust ports.

9. The thin film deposition apparatus as claimed in claim 1, wherein the plurality of linear nozzle parts are separated from a substrate deposited with a thin film and positioned upwardly with respect to the substrate.

10. The thin film deposition apparatus as claimed in claim 9, further comprising a transferring device supporting the substrate and transferring the substrate.

11. The thin film deposition apparatus as claimed in claim 1, further comprising a plasma generation electrode installed inside the first reaction gas pipe.
